(19) United States
(12) Patent Application Publication
(10) Pub. No.: US 2007/0257735 A1
(43) Pub. Date: Nov. 8, 2007

(54) High frequency divider with input-sensitivity compensation

(75) Inventors: Yi-Jen Chan, Jhongli City (TW); Fan-Hsiu Huang, Danshuei Township (TW)

Correspondence Address: TROXELL LAW OFFICE PLLC;SUITE 1404, 5205 LEESBURG PIKE, FALLS CHURCH, VA, 22041, US

(73) Assignee: National Central University

(21) Appl. No.: 11/416,224

(22) Filed: May 3, 2006

(51) Int. Cl. H03L 7/00

(52) U.S. Cl. 331/16

(57) ABSTRACT

A frequency divider, which has a cross-coupled inductor-capacitor (LC) structure or a ring structure, is inputted with a direct current (DC) control voltage from an input terminal. By doing so, the frequency divider can adjust an oscillation frequency; and further compensate the input power sensitivity, lower the power consumption and increase the division range. The frequency divider can be used in high-band/high-speed digital or analog communication systems.

### FIELD OF THE INVENTION

The present invention relates to a frequency divider; more particuiarly, relates to, without changing a circuit structure, ad justing an oscillation frequency to obtain a compensation to a power sensitivity of an input, to reduce a power consumption of the input and to increase a frequency range for division.

### DESCRIPTION OF THE RELATED ARTS

A general injection locked frequency divider has a structure of an oscillator, an LC structure or a ring structure, where signals are injected from an in injection terminal. When an injected signal has a phase synchronization to an inner oscillation signal, a division is done. The operative frequency of the circuit is decided by an oscillator, where the power required is low enough to be used in circuits with low power. Such a circuit is characterized in a big division ratio, a small locked frequency and a small phase noise.

Generally speaking, the injection locked frequency divider has a smaller locked frequency than that of a static frequency divider so that an operation under a frequency deviated from the oscillation frequency requires an increased input signal power level to get a correct state of a division. Yet, regarding the operation under the deviated frequency, because the inner oscillating signal is no more synchronization with the input signal, a division is impossible even through the power level of the input signal is increased. Therefore, the injection locked frequency divider is only suitable for narrow-band communication systems with low transferring rates.

A prior art is proclaimed in Taiwan, called “A frequency divider circuit”, where a multi-phase signal according to an input signal is outputted and the outputted signal has a frequency obtained by equally dividing a period (integer) of the frequency of the in put signal. The prior art comprises an N-stage ringed-amplifier circuit and a current-deviation modulator circuit, where the current-deviation modulator circuit produces an alternating current having the same frequency as that of the input signal. Then the alternating current is injected into the ringed-amplifier circuit to obtain a fixed oscillation frequency. After the ringed-amplifier circuit obtains a state of a steady oscillation, an output terminal of the ringed-amplifier circuit outputs a signal equally dividing the period and the frequency is a 1/N part of the reference frequency.

Another prior art is revealed in Taiwan, named “A frequency divider”, comprising a divider to produce a first clock and a second clock according to an input clock; a switching device to out putting an output clock of the first clock upon an input switching signal of a first state, or of the second clock upon an output switching signal of a second state; and a switching control device to produce the input or output switching signal for the first state or the second state and to output the input or output switching signal to the switching device according to the frequency of the output clock from the switching device.

Although the prior arts have the frequency-division function, the ranges for frequency division are narrow. For a wider range for frequency division, a bigger input power or a change in circuit structure is required. Hence, the prior arts do not fulfill users' requests on actual use.

### SUMMARY OF THE INVENTION

The main purpose of the present invention is to ad just an oscillation frequency by in putting a DC control voltage without changing the circuit structure to maintain a lowest power strength of an in put signal, to reduce a power consumption of the input signal and to increase the frequency range for dividing the input signal.

To achieve the above purpose, the present invention is a high frequency divider with input-sensitivity compensation, comprising an input terminal, an injection transistor, a first inductance, a second inductance, a first transistor, a second transistor, a third transistor, a fourth transistor, a first output buffer, a second output buffer, a first output terminal, a second output terminal, and a voltage control terminal, where the above components are connected electrically to form a cross-coupled LC structure; a DC control voltage is inputted from the voltage control terminal to change capacities of the third transistor and the fourth transistor to adjust an oscillation frequency. Or, the frequency divider can be comprised of a plurality of inverters, an input terminal, an injection transistor, an output buffer, an output terminal and a voltage control terminal, where the above components are connected electrically to form a ring structure; the inverter comprises a fifth transistor, a sixth transistor and a seventh transistor connected electrically; a DC control voltage is inputted from the voltage control terminal to change an RC time of each inverter to adjust an oscillation frequency. Accordingly, a novel high frequency divider with input-sensitivity compensation is obtained.

### BRIEF DESCRIPTIONS OF THE DRAWINGS

The present invention will be better understood from the following detailed descriptions of the preferred embodiments according to the present invention, taken in conjunction with the accompanying drawings, in which

FIG. 1 is a structural view showing a first preferred embodiment according to the present invention;

FIG. 2A is a structural view of the second preferred embodiment;

FIG. 2B is a structural view of the inverter;

FIG. 3 is a view showing a range of input sensitivity for the frequency division under a fixed oscillation frequency;

FIG. 4 is a view showing the relation between the DC control voltage and the oscillation frequency obtained thereby; and

FIG. 5 is a view showing a range of spectrum for the frequency division with an adjusted oscillation frequency.

### DESCRIPTION OF THE PREFERRED EMBODIMENTS

The following descriptions of the preferred embodiments are provided to understand the features and the structures of the present invention.

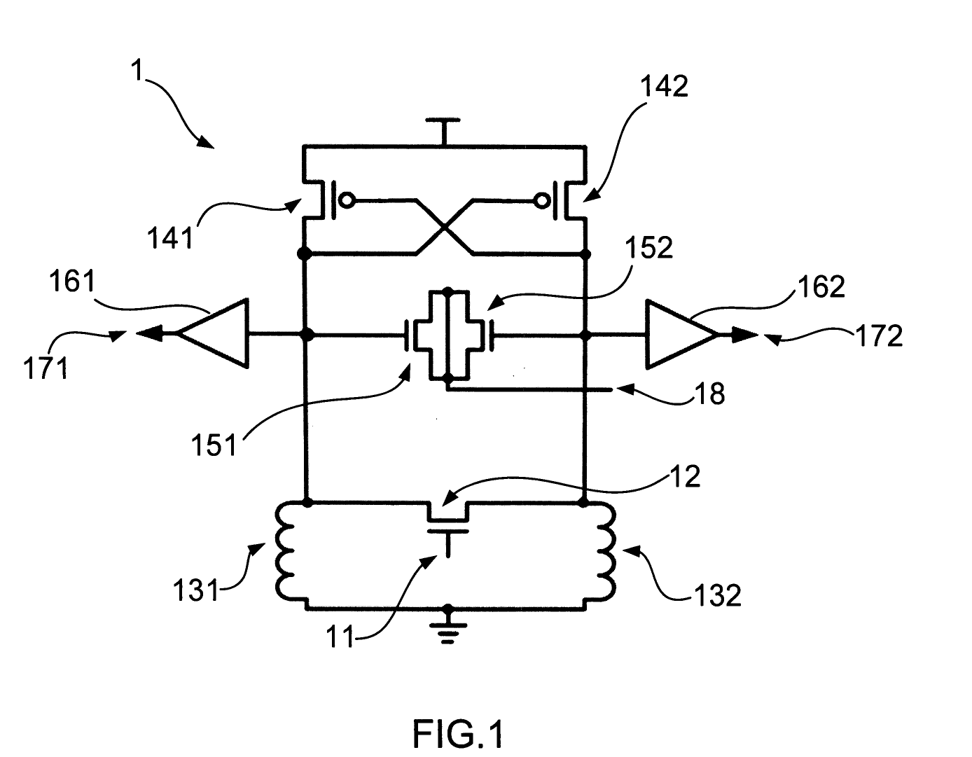

Please refer to FIG. 1, which is a structural view showing the first preferred embodiment according to the present invention. As shown in the figure, the present invention is a high frequency divider with input-sensitivity compensation, comprising an input terminal 11, an injection transistor 12, a first inductance 131, a second inductance 132, a first transistor 141, a second transistor 142, a third transistor 151, a fourth transistor 152, a first output buffer 161, a second output buffer 162, a first output terminal 171 (out+), a second output terminal 172 (out−), and a voltage control terminal, where the above components are connected electrically to form a cross-coupled inductor-capacitor (LC) structure.

Each transistor 141, 142, 151, 152 in the components is a metal oxide semiconductor (MOS) transistor, a high electron mobility transistor (HEMT), a bipolar junction transistor (BJT) or a heterojunction bipolar transistor (HBT). The third transistor 151 and the fourth transistor 152 are va varactors or diodes. The first inductance 131 and the second inductance 132 are spiral or curved (meander type). And the first output buffer 161 and the second output buffer 162 both have a structure of an emitter-coupled logic (ECL), a common mode logic (CML), a positive-ECL (PECL) or a low voltage differential signaling (LVDS) circuit.

The frequency divider 1 according to the present invention is an injection locked frequency divider with a cross-coupled LC structure. The frequency divider 1 can be an oscillator. A direct-current (DC) control voltage is inputted from the voltage control terminal 18 into the third transistor 151 and the fourth transistor 152 to change capacities of the third transistor 151 and the fourth transistor 152. A first transistor 141 and a second transistor 142 are used coordinately with negative impedances to eliminate positive resistances of the first inductance 131 and the second inductance 132. Thus, an oscillation frequency is obtained from the frequency divider 1. By doing so, before inputting any signal, the frequency divider 1 obtains an oscillation frequency through inputting a DC control voltage for an adjustment in advance. Then, the oscillation frequency can be adjusted under different levels by controlling the DC control voltage.

In the other hand, an input signal for frequency division is inputted from the input terminal 11, whose frequency is an even times to the oscillation frequency of the frequency divider 1. After the division, the frequency-divided input signal is amplified by the first output buffer 161 and the second output buffer 162 to be outputted from the first output terminal 171 and the second output terminal 172, where the outputted divisor of the frequency divider 1 is an even number.

But, if the frequency of the input signal is deviated from the oscillation frequency and therefore is not divided, a DC control voltage is in inputted from the voltage control terminal 18 to change the capacities of the third transistor 151 and the fourth transistor 152 to further adjust the oscillation frequency into a reciprocal of an even times of the frequency of the input signal.

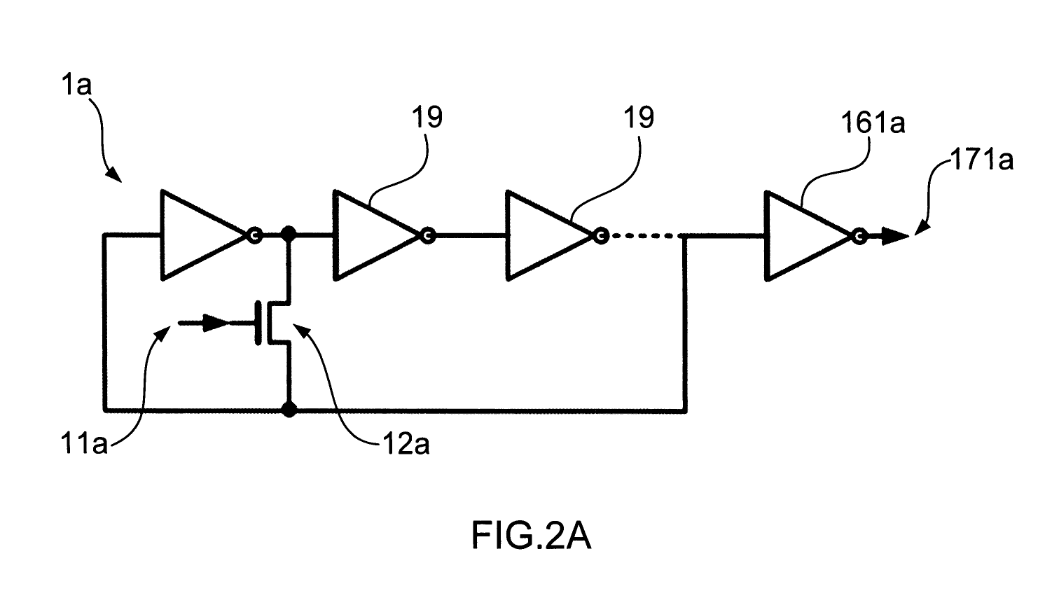

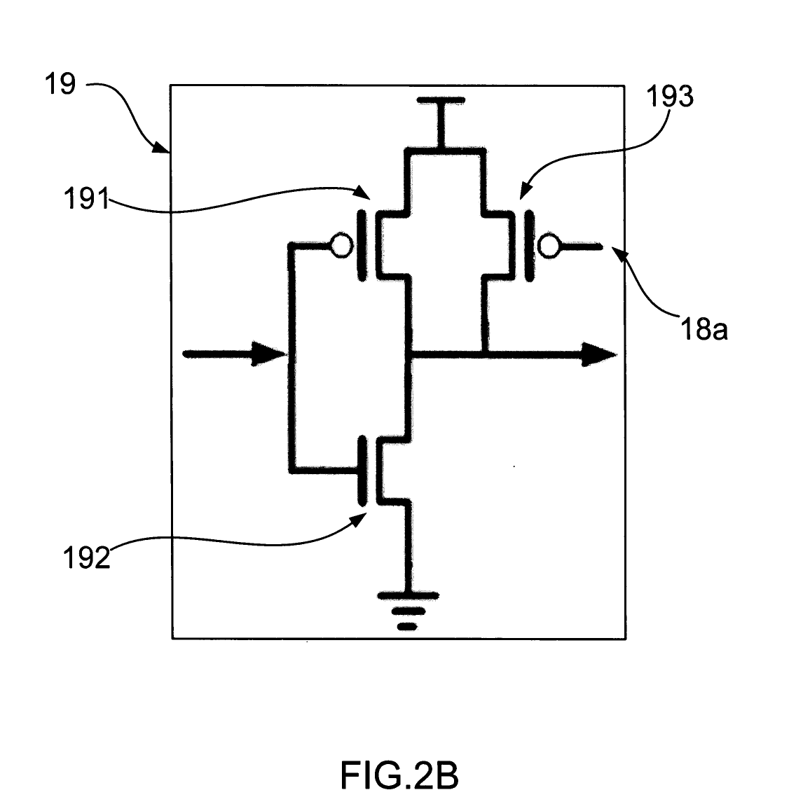

Please refer to FIG. 2A and FIG. 2B, which are structural views of the second preferred embodiment and the inverter. As shown in the figures, the present invention is a high frequency divider with input-sensitivity compensation, comprising a plurality of inverters 19, an input terminal 11a, an injection transistor 12a, an output buffer 161a, an output terminal 171a and a voltage control terminal 18a, where the inverters 19 are connected serially and the components are connected electrically to obtain an injection locked frequency divider 1a with a ring structure.

The plurality of inverters 19 has an odd number of inverters; and each inverter 19 comprises a fifth transistor 191, a sixth transistor 192 and a seventh transistor 193 connected electrically, where the fifth transistor 191 and the sixth transistor 192 are inverters to obtain RC time; and the seventh transistor 193 is a delay-time adjusting transistor. By inputting a DC control voltage to each inverter 19 from each voltage control terminal 18a to change the RC time, the oscillation frequency is changed into a reciprocal of an even times of frequency of an input signal so that a compensation to an input power sensitivity is obtained.

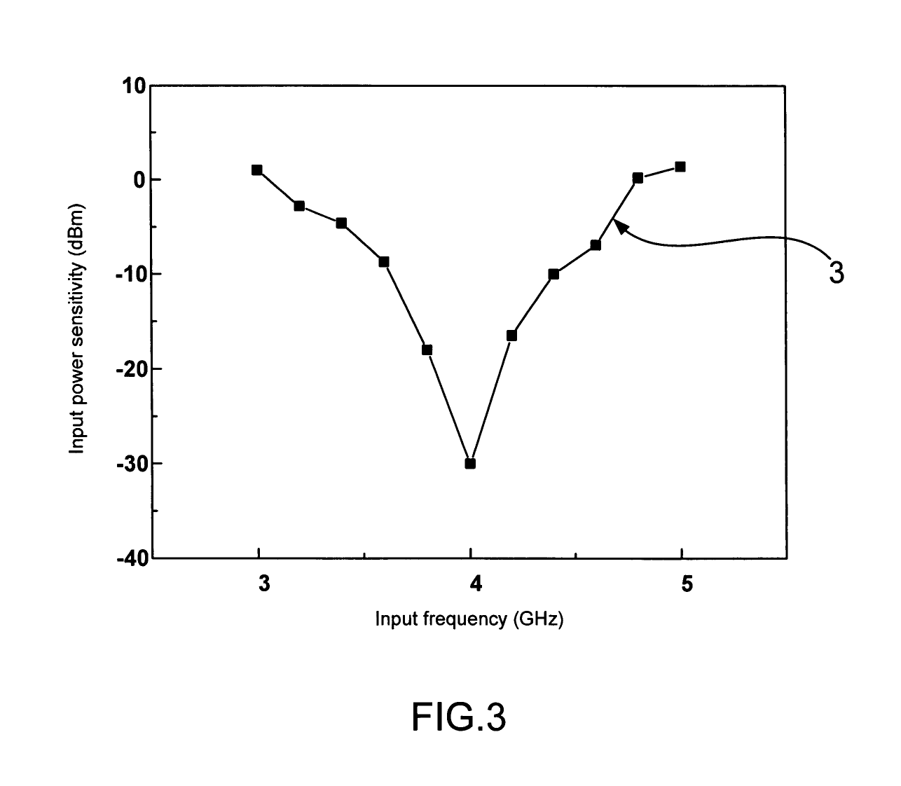

Please refer to FIG. 3, which is a view showing a range of input sensitivity for the frequency division under a fixed oscillation frequency. As shown in the figure, a first sensitivity curve 3 shows a frequency range between 3 GHz (gigahertz) and 5 GHz for the input signal to be divided when the oscillation frequency is 2 GHz. When the input signal has a frequency of 4 GHz, which is 2 times (an even times) to the oscillation frequency, the input signal can be divided with a smallest power sensitivity (−30 dBm).

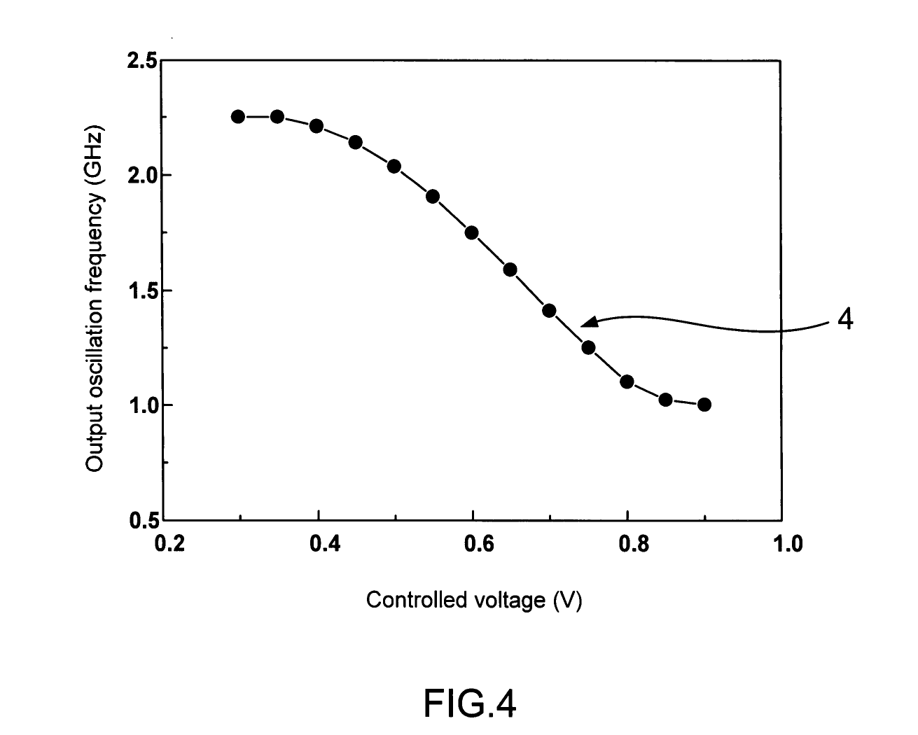

Please refer to FIG. 4, which is a view showing the relation between the DC control voltage and the oscillation frequency obtained thereby. As shown in the figure, the curve 4 shows that the frequency divider according to the present invention ad adjusts an oscillation frequency by inputting a DC control voltage from the voltage control terminal. The oscillation frequency changes according to the value of the DC control voltage. Such as, a DC control voltage of 0.4 volt (V) being inputted obtains an oscillation frequency between 2.0 GHz and 2.25 GHz; a DC control voltage of 0.6V being inputted obtains an oscillation frequency between 1.75 Hz and 2.0 GHz.

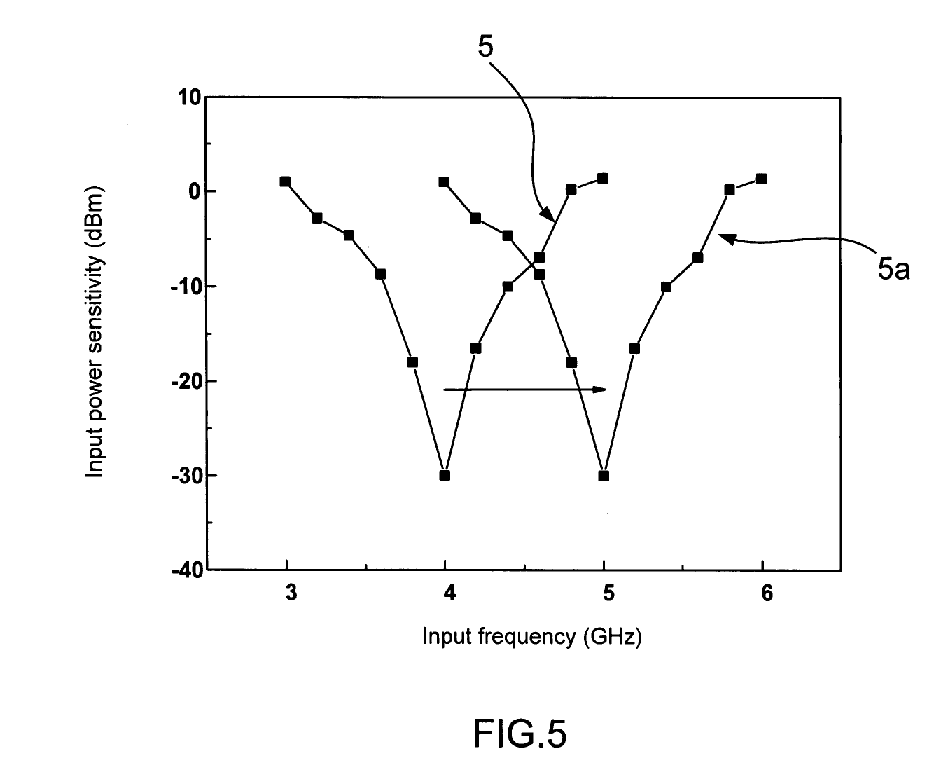

Please refer to FIG. 5, which is a view showing a range of spectrum for the frequency division with an adjusted oscillation frequency. As shown in the figure, with an oscillation frequency of 2 GHz and an output divisor of 2, a frequency between 3 GHz and 5 GHz is required for an input signal to be divided (as shown by a second spectrum curve 5). When the frequency for an input signal is 4 GHz, which is 2 times to the oscillation frequency, the required power sensitivity for the input signal is −30 dBm. And when the frequency of the input signal is greater than or smaller than the oscillation frequency, the oscillation frequency can be adjusted into a half of the frequency of the input signal to maintain the function of frequency division. For example, when the oscillation frequency is 2 GHz and the frequency of the input signal is 5 GHz, the oscillation frequency can be ad adjusted into 2.5 GHz (as shown by a third spectrum curve 5a) as a half of the oscillation frequency so that the power sensitivity of the input signal remains −30 dBm as a compensation to the power sensitivity.

To sum up, the present invention is a high frequency divider with input-sensitivity compensation, where, without changing the circuit, a DC control voltage is controlled to adjust an oscillation frequency so that a power sensitivity of the input signals is lowered, the consumption of input power is reduced and the frequency range for division is increased.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A high frequency divider with input-sensitivity compensation comprising components of:
an input terminal;
an injection transistor;
a first inductance;
a second inductance;
a first transistor;
a second transistor;
a third transistor;
a fourth transistor;
a first output buffer;
a second output buffer;
a first output terminal;
a second output terminal;
a voltage controller,
wherein said components are connected electrically to obtain a cross-coupled inductor-capacitor (LC) structure.

2. The frequency divider according to claim 1,
where in said frequency divider is an oscillator; and
wherein a direct-current (DC) control voltage is inputted into said voltage control terminal to obtain an oscillation frequency from said frequency divider.

3. The frequency divider according to claim 2,
wherein said oscillation frequency is ad adjusted under different levels by controlling a voltage value of said DC control voltage.

4. The frequency divider according to claim 2,
wherein said oscillation frequency is a reciprocal of an even times of a frequency of an input signal.

5. The frequency divider according to claim 4,
wherein said input signal is a sine wave.

6. The frequency divider according to claim 4,
wherein said input signal has a frequency deviated from said oscillation frequency; and
wherein a DC control voltage is inputted into a voltage control terminal to adjust said oscillation frequency into said reciprocal of said even times of said frequency of said input signal when said input signal has a frequency being deviated from said oscillation frequency.

7. The frequency divider according to claim 1,
wherein said third transistor is selected from a group consisting of a varactor and a diode.

8. The frequency divider according to claim 1,
wherein said fourth transistor is selected from a group consisting of a varactor and a diode.

9. The frequency divider according to claim 1,
wherein said injection transistor, said first transistor, said second transistor, said third transistor, said fourth transistor are each selected from a group consisting of a metal oxide semiconductor (MOS) transistor, high electron mobility transistor (HEMT), a bipolar junction transistor (BJT) and a Heterojunction Bipolar Transistor (HBT).

10. The frequency divider according to claim 1,
wherein said first inductance has a shape selected from a group consisting of a spiral shape and a curved shape.

11. The frequency divider according to claim 1,
wherein said second inductance has a shape selected from a group consisting of a spiral shape and a curved shape.

12. The frequency divider according to claim 1,
wherein said output buffer has a structure selected from a group consisting of an emitter-coupled logic (ECL), a common mode logic (CML), a positive-ECL (PECL) and a low voltage differential signaling (LVDS) circuit.

13. The frequency divider according to claim 1,
wherein said frequency divider outputs a divisor of an even number.

14. A high frequency divider with input-sensitivity compensation, comprising components of:
a plurality of inverters
an input terminal;
an injection transistor;
an output buffer; and
an output terminal,
wherein said plurality of inverters are connected serially; and
wherein said components are connected electrically to obtain a ring structure.

15. The frequency divider according to claim 14,
wherein said plurality of inverters has an odd number of inverters.

16. The frequency divider according to claim 14,
wherein each inverter in said plurality of inverters comprises a fifth transistor, a sixth transistor and a seventh transistor; and
wherein said fifth transistor, said sixth transistor and said seventh transistor are connected electrically.

17. The frequency divider according to claim 16,
wherein said seventh transistor is a delay-time adjusting transistor.

18. The frequency divider according to claim 14,
wherein said voltage control terminal receives an in put of a DC control voltage to adjust a Resistor-Capacitor (RC) time of each inverter to adjust an oscillation frequency.
